(19) United States
(12) Patent Application Publication
(10) Pub. No.: US 2025/0063872 A1
(43) Pub. Date: Feb. 20, 2025

(54) DISPLAY DEVICE

(71) Applicant: Samsung Display Co., Ltd., Yongin-si (KR)

(72) Inventors: DAEHYUK IM, Yongin-si (KR); YOUN-WOONG KANG, Yongin-si (KR); DONGHYUN LEE, Yongin-si (KR)

(21) Appl. No.: 18/680,467

(22) Filed: May 31, 2024

(30) Foreign Application Priority Data
Aug. 16, 2023 (KR) 10-2023-0107227

(51) Int. Cl. H01L 33/62; H01L 25/075; H01L 25/16; H01L 33/38; H05K 1/02

(52) U.S. Cl. CPC H01L 33/62; H01L 25/0753; H01L 25/167; H01L 33/38; H05K 1/028; H05K 2201/10128

(57) ABSTRACT

A display device includes first and second circuit boards connected to a display panel defining a display area and a non-display area, and including a first sub-base layer overlapping the display area and the non-display area, a second sub-base layer above the first sub-base layer, a connection electrode between the first sub-base layer and the second sub-base layer, and electrically connected to a signal line, and pad electrodes exposed through an opening in the first sub-base layer, electrically connected to the connection electrode, and including first pad electrodes electrically connected to the first circuit board, and extending in a direction, and second pad electrodes electrically connected to the second circuit board, spaced apart from the first pad electrodes in the direction, and extending in an opposite direction, and a circuit layer including a transistor, and at least one signal line connected to the transistor.

### CROSS-REFERENCE TO RELATED APPLICATION

The present application claims priority to, and the benefit of, Korean Patent Application No. 10-2023-0107227, filed on Aug. 16, 2023, in the Korean Intellectual Property Office, the entire disclosure of which is incorporated herein by reference.

### BACKGROUND

### 1. Field

Embodiments of the present disclosure described herein relate to a display device of which a rear surface may be bonded to a circuit board.

### 2. Description of the Related Art

Electronic devices, such as smart phones, tablets, laptop computer, vehicle navigation systems, and smart televisions have been developed. These electronic devices are provided with display devices to provide information.

Various types of display devices have been developed to satisfy user experience (UX)/user interface (UI) of a user. Display devices have been developed to provide a wide display area and a narrow non-display area.

### SUMMARY

Embodiments of the present disclosure provide a display device having a reduced non-display area.

According to one or more embodiments, a display device includes a first circuit board, a second circuit board, and a display panel electrically connected to the first circuit board and the second circuit board, defining a display area and a non-display area, and including a base layer including a first sub-base layer overlapping the display area and the non-display area, a second sub-base layer above the first sub-base layer, a connection electrode between the first sub-base layer and the second sub-base layer, and electrically connected to a signal line, and pad electrodes exposed through an opening defined in the first sub-base layer, electrically connected to the connection electrode, and including first pad electrodes electrically connected to the first circuit board, and extending in a first direction, and second pad electrodes electrically connected to the second circuit board, spaced apart from the first pad electrodes in the first direction, and extending in an opposite direction to the first direction, and a circuit layer above the base layer, and including a transistor, and at least one signal line connected to the transistor.

The first circuit board may include a first base film, and a first bump electrode above the first base film, wherein the second circuit board includes a second base film, and a second bump electrode above the second base film.

The first circuit board may include a first base film, and first bump electrodes above the first base film, wherein the second circuit board includes a second base film, and second bump electrodes above the second base film and facing the first bump electrodes in the first direction.

The first pad electrodes may respectively contact the first bump electrodes, wherein the second pad electrodes respectively contact the second bump electrodes.

The first bump electrode may include a first contact part extending beyond an edge of the first base film, wherein the second bump electrode includes a second contact part extending beyond an edge of the second base film.

The display device may further include a first metal pattern electrically connecting the first bump electrode and the first pad electrodes, and a second metal pattern electrically connecting the second bump electrode and the second pad electrodes, wherein the first metal pattern contacts the first pad electrodes and the first contact part, and wherein the second metal pattern contacts the second pad electrodes and the second contact part.

The display device may further include a first adhesive layer between the first bump electrode and the first pad electrodes, and a second adhesive layer between the second bump electrode and the second pad electrodes.

The first pad electrodes may include first main parts overlapping the first bump electrode on a plane, and first extension parts not overlapping the first bump electrode on a plane, and extending from the first main parts, wherein the second pad electrodes include second main parts overlapping the second bump electrode on a plane, and second extension parts not overlapping the second bump electrode on a plane, and extending from the second main parts.

The first main parts and the second main parts may face each other in the first direction, and may be arranged in a second direction substantially perpendicular to the first direction.

The first extension parts and the second extension parts may be alternately arranged in the second direction.

The first extension parts and the second extension parts may partially overlap each other in the second direction.

Respective widths of the first extension parts and the second extension parts may decrease along the first direction.

The first circuit board may include a bending part bent toward a lower side of the display panel, wherein a portion of the first circuit board overlaps the second circuit board on a plane.

The first pad electrodes and the second pad electrodes may overlap the non-display area.

The display device may further include an insulating layer between the pad electrodes and the connection electrode, the pad electrodes and the connection electrode being electrically connected through a contact hole defined by the insulating layer.

The display device may further include a connection pattern penetrating a portion of the base layer, wherein the signal line is above an upper surface of the second sub-base layer, and is electrically connected to a corresponding one of the pad electrodes through the connection pattern.

According to one or more embodiments, a display device includes a display panel defining a display area and a non-display area, and a first circuit board electrically connected to the display panel, and a second circuit board electrically connected to the display pane and spaced apart from the first circuit board in a first direction, wherein the display panel includes a base layer including a first sub-base layer overlapping the display area and the non-display area, a second sub-base layer above the first sub-base layer, a connection electrode between the first sub-base layer and the second sub-base layer, and electrically connected to a signal line, and pad electrodes exposed through an opening defined in the first sub-base layer, electrically connected to the connection electrode, and including first pad electrodes overlapping the first circuit board and not overlapping the second circuit board, and second pad electrodes overlapping the second circuit board and not overlapping the first circuit board, at least one of the second pad electrodes facing at least one of the first pad electrodes in a second direction that is substantially perpendicular to the first direction, and a circuit layer above the base layer, and including a transistor and at least one signal line connected to the transistor.

The first pad electrodes and the second pad electrodes may be spaced apart from each other in the first direction.

The first pad electrodes may include first main parts overlapping the first circuit board on a plane, and first extension parts not overlapping the first circuit board on a plane, and extending from the first main parts, wherein the second pad electrodes include second main parts overlapping the second circuit board on a plane, and second extension parts not overlapping the second circuit board on a plane, and extending from the second main parts.

The first extension parts and the second extension parts may be alternately arranged in the second direction.

### BRIEF DESCRIPTION OF DRAWINGS

The above and other objects and features of the present disclosure will become apparent by describing in detail embodiments thereof with reference to the accompanying drawings.

FIG. 1 is a perspective view of an electronic device according to one or more embodiments of the present disclosure.

FIG. 2 is an exploded perspective view of the electronic device according to one or more embodiments of the present disclosure.

FIG. 3 is a cross-sectional view of a display device along the line I-I′ of FIG. 2.

FIG. 4 is a schematic cross-sectional view of a display module according to one or more embodiments of the present disclosure.

FIG. 5 is a plan view of a display panel according to one or more embodiments of the present disclosure.

FIG. 6 is a cross-sectional view of the display module according to one or more embodiments of the present disclosure.

FIG. 7A is an enlarged view of a portion of the display device according to the present disclosure.

FIG. 7B is a cross-sectional view of the display module along the line II-II′ of FIG. 7A.

FIG. 8A is an enlarged view of a portion of the display device according to the present disclosure.

FIG. 8B is an enlarged view of a portion of the display device according to the present disclosure.

FIG. 9 is an enlarged view of a portion of the display device according to the present disclosure.

FIG. 10A is a cross-sectional view of the display module along the line III-III′ of FIG. 9.

FIG. 10B is a cross-sectional view of the display module along the line IV-IV′ of FIG. 9

FIG. 10C is an enlarged view of area AA′ of FIG. 10A.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

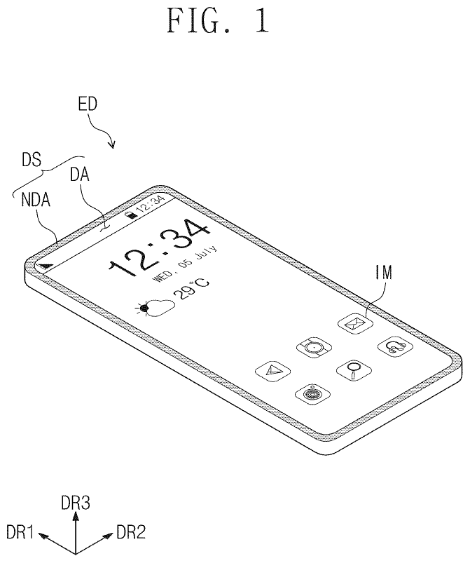

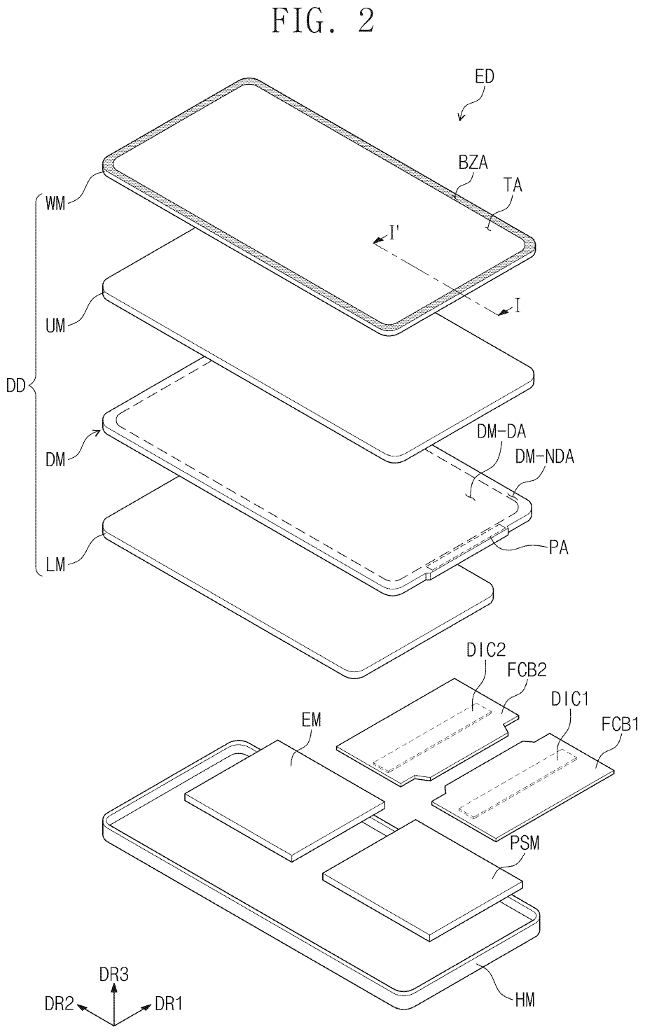

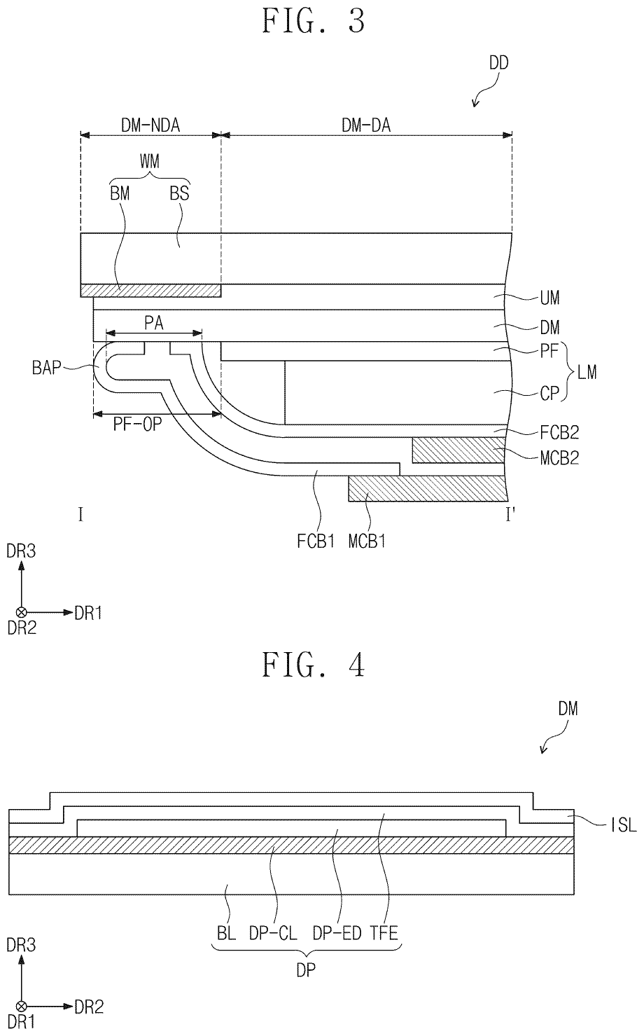

FIG. 1 is a perspective view of an electronic device according to one or more embodiments of the present disclosure. FIG. 2 is an exploded perspective view of the electronic device according to one or more embodiments of the present disclosure. FIG. 3 is a cross-sectional view of a display device along the line I-I′ of FIG. 2.

Referring to FIGS. 1, an electronic device ED according to one or more embodiments of the present disclosure may include a display surface DS defined by a first direction DR1 and a second direction DR2 intersecting the first direction DR1. The electronic device ED may provide an image IM to a user through the display surface DS.

The display surface DS may include a display area DA, and a non-display area NDA around the display area DA. The display area DA may be an area that displays the image IM, and the non-display area NDA may be an area that does not display the image IM. The non-display area NDA may surround the display area DA. However, the present disclosure is not limited thereto, and the shape of the display area DA and the shape of the non-display area NDA may be modified.

Hereinafter, a direction substantially perpendicular to a plane defined by the first direction DR1 and the second direction DR2 is defined as a third direction DR3. The third direction DR3 serves as a standard for distinguishing a front surface and a rear surface of each of members. In the present specification, the wording “on a plan view” may be defined as a state in which a display device DD is viewed in the third direction DR3.

In one or more embodiments of the present disclosure, the electronic device ED may be a foldable electronic device that may be folded about a folding axis. The folding axis may be parallel to the first direction DR1 or the second direction DR2, and a folding area may be defined in a portion of the display area DA. The electronic device ED may be in-folded such that the display areas DA face each other or out-folded such that the display areas DA are folded away from each other.

As illustrated in FIG. 2, the electronic device ED may include the display device DD, an electronic module EM, a power supply module PSM, and a housing HM. FIG. 2 briefly illustrates the electronic device ED, and the electronic device ED may further include a mechanical structure (e.g., a hinge) for controlling an operation (e.g., folding or rolling) of the display device DD.

The display device DD generates the image IM and detects an external input. The display device DD includes a window WM, an upper member UM, a display module DM, a lower member LM, flexible circuit boards FCB1 and FCB2, and driver integrated circuits DIC1 and DIC2. The upper member UM includes members arranged on the display module DM, and the lower member LM includes members arranged under the display module DM.

The window WM provides a front surface of the electronic device ED. The window WM includes a transmissive area TA and a bezel area BZA. The display area DA and the non-display area NDA of the display surface DS illustrated in FIG. 1 may be defined by the transmissive area TA and the bezel area BZA. The transmissive area TA is an area through which an image passes, and the bezel area BZA is an area that covers a structure/member located under the window WM.

The display module DM includes a display area DM-DA and a non-display area DM-NDA respectively corresponding to the display area DA and the non-display area NDA illustrated in FIG. 1. In the present specification, an expression “an area/part and an area/part correspond to each other” means that the area/part and the area/part overlap each other and is not limited to the same area.

A pad area PA is located on one side of the non-display area DM-NDA. The pad area PA is an area that is electrically bonded (or connected) to the flexible circuit boards FCB1 and FCB2, which will be described below. In one or more embodiments, the pad area PA is defined on a rear surface of the display module DM.

The display module DM has a substantially quadrangular shape. Here, the “substantially quadrangular shape” includes not only a quadrangular shape in the mathematical sense but also a shape similar to the quadrangular shape, which may be recognized as a quadrangular shape by a user. For example, a substantially quadrangular shape may include a quadrangular shape having rounded corner areas. Further, in the substantially quadrangular shape, edges of the display module DM are not limited to a straight shape, and the edges may include curved areas.

The upper member UM may include a protective film or optical film. The optical film may include a polarizer and a retarder to reduce reflection of external light. The lower member LM may include a protective film that protects the display module DM, a support member that supports the display module DM, a digitizer, or the like. The upper member UM and the lower member LM will be described below in detail.

The flexible circuit boards FCB1 and FCB2 may include the first flexible circuit board (or a first circuit board) FCB1 and the second flexible circuit board (or a second circuit board) FCB2. The first flexible circuit board FCB1 and the second flexible circuit board FCB2 are located under the display module DM. The first flexible circuit board FCB1 and the second flexible circuit board FCB2 may be bonded to a rear surface of the display module DM. The first flexible circuit board FCB1 electrically connects the display module DM and a first main circuit board MCB1 (see FIG. 3), and the second flexible circuit board FCB2 electrically connects the display module DM and a second main circuit board MCB2 (see FIG. 3). The first flexible circuit board FCB1 and the second flexible circuit board FCB2 include at least one insulating layer and at least one conductive layer. The conductive layer may include a plurality of signal lines.

The driver integrated circuits DIC1 and DIC2 may include the first driver integrated circuit DIC1 and the second driver integrated circuit DIC2. The first driver integrated circuit DIC1 may be mounted on the first flexible circuit board FCB1. The second driver integrated circuit DIC2 may be mounted on the second flexible circuit board FCB2. The first driver integrated circuit DIC1 and the second driver integrated circuit DIC2 may include a driving circuit for driving pixels of the display module DM, for example, a data-driving circuit. FIG. 2 illustrates a structure in which the driver integrated circuits DIC1 and DIC2 are mounted on the flexible circuit boards FCB1 and FCB2, but the present disclosure is not limited thereto. For example, the driver integrated circuits DIC1 and DIC2 may be mounted on the display module DM or a main circuit board.

The electronic module EM may include a control module, a wireless communication module, an image input module, a sound input module, a sound output module, a memory, an external interface module, or the like. The electronic module EM may include the main circuit board, and the modules may be mounted on the main circuit board or may be electrically connected to the main circuit board through the flexible circuit board. The electronic module EM is electrically connected to the power supply module PSM.

In one or more embodiments, the electronic device ED may further include an electro-optical module. The electro-optical module may be an electronic component that outputs or receives an optical signal. The electro-optical module may include a camera module and/or a proximity sensor. The camera module may capture an external image through a portion of the display module DM.

The housing HM illustrated in FIG. 2 is coupled to the display device DD, for example, the window WM, to accommodate the other modules. It is illustrated that the housing HM has an integral shape, but the present disclosure is not limited thereto. The housing HM may include a plurality of portions (e.g., a side edge portion and a bottom portion) coupled to each other.

Referring to FIG. 3, the window WM may include a base substrate BS and a bezel pattern BM located on (e.g., below) a lower surface of the base substrate BS. The base substrate BS may include a synthetic resin film or a glass substrate. The base substrate BS may have a multilayer structure. The base substrate BS may include a thin film glass substrate, a protective film located on (e.g., above) the thin film glass substrate, and an adhesive layer that bonds the thin film glass substrate and the protective film.

The bezel pattern BM, which is a colored light-shielding film, may be formed by, for example, a coating method. The bezel pattern BM may include a base material and a dye or pigment mixed with the base material. The bezel pattern BM overlaps the non-display area NDA illustrated in FIG. 1 and the bezel area BZA illustrated in FIG. 2. The bezel pattern BM may be located on the lower surface of the base substrate BS. When the base substrate BS has a multi-layer structure, the bezel pattern BM may be located between interfaces defined by a plurality of layers. For example, the bezel pattern BM may be located between the thin film glass substrate and the protective film. In one or more embodiments, the window WM may further include at least one of a hard coating layer, a fingerprint-preventing layer, and a reflection-preventing layer on an upper surface of the base substrate BS.

The upper member UM may include an upper film. The upper film may include a synthetic resin film. The synthetic resin film may include polyimide, polycarbonate, polyamide, triacetylcellulose, polymethylmethacrylate, or polyethylene terephthalate.

The upper film may absorb an external impact applied to a front surface of the display device DD. In one or more embodiments of the present disclosure, the display module DM may include a color filter that replaces a polarizing film as a reflection-preventing member, and accordingly, a front impact strength of the display device DD may be reduced. The upper film may compensate for the reduced impact strength by applying the color filter.

The upper member UM overlaps the bezel area BZA and the transmissive area TA. The upper member UM may overlap only a portion of the bezel area BZA. The portion of the bezel pattern BM may be exposed from the upper member UM. In one or more embodiments of the present disclosure, the upper member UM may be omitted. In one or more embodiments of the present disclosure, the upper member UM may be replaced with an optical film including a polarizer and a retarder.

In one or more embodiments, an adhesive layer that bonds the upper member UM and the window WM may be further included between the upper member UM and the window WM. The adhesive layer may be a pressure sensitive adhesive (PSA) film or an optically clear adhesive (OCA) member.

The display module DM is located under the upper member UM. The display module DM overlaps the bezel area BZA and the transmissive area TA. The display module DM may completely overlap the upper member UM within the bezel area BZA. A side surface of the display module DM may be aligned with a side surface of the upper member UM, and an edge of the display module DM may be aligned with an edge of the upper member UM on a plane.

The pad area PA of the display module DM within the bezel area BZA may overlap the upper member UM. A portion of the display module DM corresponding to the pad area PA may be bonded to a lower surface of the upper member UM by the adhesive layer. The pad area PA overlaps the upper member UM, and a portion of the display module DM, which overlaps the pad area PA, is coupled to the upper member UM. Thus, when the flexible circuit boards FCB1 and FCB2 are bonded to the pad area PA, the upper member UM may sufficiently support the pad area PA.

The lower member LM may include a lower film PF and a cover panel CP. In one or more embodiments of the present disclosure, the lower member LM may further include a support plate and a digitizer.

The lower film PF may expose, or may define, the pad area PA of the display module DM. The lower film PF may have a smaller size than that of the display module DM. For example, the lower film PF may overlap only the display area DM-DA of the display module DM. An open area PF-OP corresponding to the non-display area DM-NDA may be defined in the lower film PF. Alternatively, the lower film PF may have a size that substantially corresponds to the display module DM. In this case, the open area PF-OP corresponding to the pad area PA may be defined in the lower film PF. The pad area PA may be exposed through the open area PF-OP.

The lower film PF may expose the pad area PA. The lower film PF may have a smaller area than that of the display module DM. For example, the lower film PF may overlap only the display area DA. The lower film PF may have substantially the same area as that of the display module DM. The open area PF-OP corresponding to the pad area PA may be defined in the lower film PF. The pad area PA may be exposed through the open area PF-OP.

The cover panel CP may be located under the lower film PF. The cover panel CP may increase resistance against a compressive force generated by external pressure. Thus, the cover panel CP may serve to reduce or prevent deformation of the display module DM. The cover panel CP may include a flexible plastic material, such as polyimide or polyethylene terephthalate. Further, the cover panel CP may be a colored film having low light transmittance. The cover panel CP may absorb a light beam input from the outside. For example, the cover panel CP may be a black synthetic resin film. When the display device DD is viewed from a front side of the window WM, components arranged under the cover panel CP may not be visually recognized by the user.

A support plate may be further located under the cover panel CP. The support plate may include a metal material having relatively high strength. The support plate may also include a reinforced fiber composite. The support plate may include a reinforced fiber located inside a matrix part. The reinforced fiber may be a carbon fiber or a glass fiber. The matrix part may include a polymer resin. The matrix part may include a thermoplastic resin. For example, the matrix part may include a polyamide-based resin or a polypropylene-based resin. For example, the reinforced fiber composite may be carbon fiber reinforced plastic (CFRP) or glass fiber reinforced plastic (GFRP).

The first main circuit board MCB1 may be located on (e.g., below) a lower surface of the first flexible circuit board FCB1. The second main circuit board MCB2 may be located on a lower surface of the second flexible circuit board FCB2. Each of the first flexible circuit board FCB1 and the second flexible circuit board FCB2 may include an insulating film and conductive wiring lines mounted on the insulating film. Each of the first main circuit board MCB1 and the second main circuit board MCB2 may include signal lines and electronic elements. The electronic elements may be connected to the signal lines and electrically connected to the display module DM. The electronic elements generate various electrical signals, for example, signals for generating an image or signals for detecting an external input, or process detected signals. Meanwhile, a single first main circuit board MCB1 and a single second main circuit board MCB2 may be provided to correspond to each of the electrical signal for the generation and processing, and three or more first main circuit boards MCB1 and/or three or more second main circuit boards MCB2 may be provided, but the present disclosure is not limited thereto.

In one or more embodiments, the first main circuit board MCB1 may include the first driver integrated circuit DIC1 (see FIG. 2) mounted inside the first main circuit board MCB1, and the second main circuit board MCB2 may include the second driver integrated circuit DIC2 (see FIG. 2) mounted inside the second main circuit board MCB2.

The first flexible circuit board FCB1 may include a bending part BAP. In detail, the bending part BAP may be bent toward a lower side of the display module DM about a bending axis parallel to the second direction DR2. By bending the bending part BAP, the first flexible circuit board FCB1 may overlap a portion of the second flexible circuit board FCB2 on a plane.

Referring to FIGS. 2 and 3, the flexible circuit boards FCB1 and FCB2 are bonded to the rear surface of the display module DM (rear surface bonding). Because the non-display area DM-NDA of the display module DM is not bent, defects that occur during the bending may be reduced or prevented in the display module DM and the non-display area DM-NDA. Further, an area of the bezel area BZA of the window WM for covering the non-display area DM-NDA of the display module DM may be reduced.

FIG. 4 is a schematic cross-sectional view of a display module according to one or more embodiments of the present disclosure.

Referring to FIG. 4, the display module DM may include the display panel DP and an input-sensing layer ISL. The display panel DP may include a base layer BL, a circuit layer DP-CL, a display element layer DP-ED, and an encapsulation layer TFE.

The circuit layer DP-CL is located on (e.g., above) an upper surface of the base layer BL. The base layer BL may be a flexible substrate that may be bent, folded, and rolled. The base layer BL may be a glass substrate, a metal substrate, a polymer substrate, or the like. However, one or more embodiments of the present disclosure is not limited thereto, and the base layer BL may be an inorganic layer, an organic layer, or a composite material layer. Substantially, the base layer BL has the same shape as that of the display panel DP.

The base layer BL may have a multilayer structure. For example, the base layer BL may include a first synthetic resin layer, a second synthetic resin layer, and an inorganic layer located therebetween. Each of the first and second synthetic resin layers may include a polyimide-based resin, but the present disclosure is not for example limited thereto.

The circuit layer DP-CL may be located on the base layer BL. The circuit layer DP-CL may include a plurality of insulating layers, a plurality of semiconductor patterns, a plurality of conductive patterns, and the signal lines. The circuit layer DP-CL may include a driving circuit of a pixel. Hereinafter, unless otherwise specified, when component A and component B are arranged on the same layer, it may be interpreted that component A and component B are formed by the same process and thus include the same material or has the same laminated structure. The conductive patterns or the semiconductor patterns arranged on the same layer may be interpreted as described above.

The display element layer DP-ED may be located on the circuit layer DP-CL. The display element layer DP-ED may include a light-emitting element. For example, the light-emitting element may include an organic light-emitting material, an inorganic light-emitting material, an organic-inorganic light-emitting material, a quantum dot, a quantum rod, a micro-light-emitting diode (LED), or a nano-LED.

The encapsulation layer TFE may be located on the display element layer DP-ED. The encapsulation layer TFE may protect the display element layer DP-ED, i.e., the light-emitting element, from foreign substances, such as moisture, oxygen, and dust particles. The encapsulation layer TFE may include at least one inorganic encapsulation layer. The encapsulation layer TFE may include a laminated structure of a first inorganic encapsulation layer/an organic encapsulation layer/a second inorganic encapsulation layer.

The input-sensing layer ISL may directly be located on the display panel DP. The input-sensing layer ISL may detect an input of a user using, for example, an electromagnetic induction method or a capacitance method. The display panel DP and the input-sensing layer ISL may be formed through a continuous process. Here, the aspect that the input-sensing layer ISL is directly located on the display panel DP may mean that a third component is not located between the input-sensing layer ISL and the display panel DP. That is, a separate adhesive layer may not be located between the input-sensing layer ISL and the display panel DP.

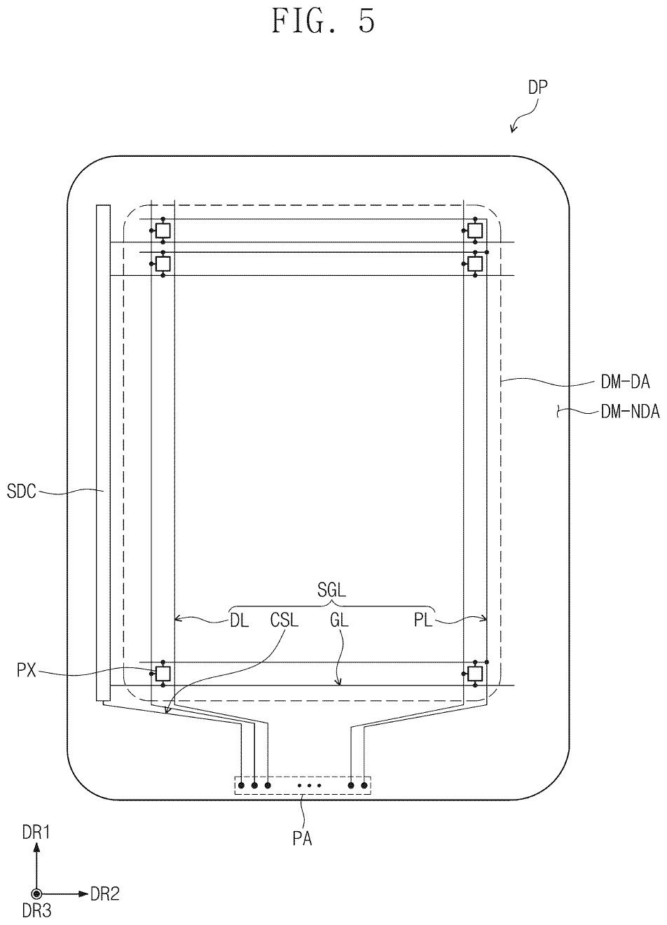

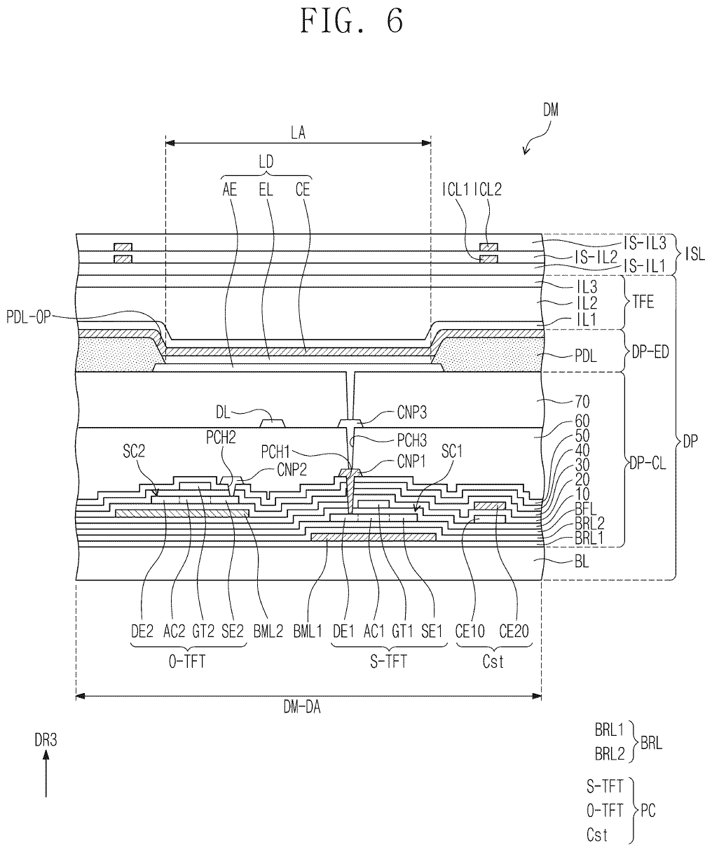

FIG. 5 is a plan view of a display panel according to one or more embodiments of the present disclosure. FIG. 6 is a cross-sectional view of the display module according to one or more embodiments of the present disclosure.

As illustrated in FIG. 5, the display panel DP may include a scan-driving circuit SDC, a plurality of signal lines SGL, and a plurality of pixels PX. The plurality of pixels PX are arranged in the display area DM-DA. Each of the pixels PX includes a light-emitting element and a pixel-driving circuit connected thereto. The scan-driving circuit SDC, the plurality of signal lines SGL, and the pixel-driving circuit may be included in the circuit layer DP-CL illustrated in FIG. 4.

The scan-driving circuit SDC may include a gate-driving circuit. The gate-driving circuit generates a plurality of scan signals and sequentially outputs the plurality of scan signals to a plurality of scan lines GL, which will be described below. The scan-driving circuit SDC may further include a light-emitting-driving circuit that is distinguished from the gate-driving circuit. The light-emitting-driving circuit may output scan signals to another group of scan lines.

The scan-driving circuit SDC may include a plurality of thin film transistors formed through the same process as that of the pixel-driving circuit, for example, a low temperature polycrystalline silicon (LTPS) process or a low temperature polycrystalline oxide (LTPO) process.

The plurality of signal lines SGL include the scan lines GL, data lines DL, a power line PL, and a control signal line CSL. Each of the scan lines GL is connected to a corresponding pixel PX among the plurality of pixels PX, and each of the data lines DL is connected to a corresponding pixel PX among the plurality of pixels PX. The power line PL is connected to the plurality of pixels PX. The data lines DL provide data signals to the pixels PX. The control signal line CSL may provide control signals to the scan-driving circuit SDC.

A plurality of power lines PL may be provided. For example, the power line PL may include a first power line that receives a first power voltage, and a second power line that receives a second power voltage having a higher level than that of the first power voltage. The first power voltage is provided to the pixels PX through the first power line, and the second power voltage is provided to the pixels PX through the second power line. Although one control signal line CSL is illustrated in FIG. 5, a plurality of control signal lines CSL may be provided.

The scan lines GL, the data lines DL, and the power line PL may overlap the display area DM-DA and the non-display area DM-NDA, and the control signal line CSL may overlap the non-display area DM-NDA. Distal ends of the plurality of signal lines SGL may be aligned on one side of the non-display area DM-NDA. The plurality of signal lines SGL may have an integral shape but may include a plurality of parts arranged on different layers. Different parts divided by the insulating layer may be connected through a contact hole passing through the insulating layer. For example, the data lines DL may include a first part located in the display area DM-DA, and a second part located in the non-display area DM-NDA at a different layer from that of the first part. The first part and the second part may include different materials and have different laminated structures.

The plurality of signal lines SGL may be electrically connected to the main circuit boards MCB1 and MCB2 illustrated in FIG. 3 through the pad area PA.

FIG. 6 illustrates a cross section of the display module DM corresponding to the pixel PX of FIG. 5.

A pixel-driving circuit PC that drives a light-emitting element LD may include a plurality of pixel-driving elements. The pixel-driving circuit PC may include a plurality of transistors S-TFT and O-TFT and a capacitor Cst. The plurality of transistors S-TFT and O-TFT may include the silicon transistor S-TFT and the oxide transistor O-TFT. FIG. 6 illustrates the silicon transistor S-TFT and the oxide transistor O-TFT. The pixel-driving circuit PC of FIG. 6 is merely one or more embodiments, and the configuration of the pixel-driving circuit PC is not necessarily limited thereto. The pixel-driving circuit PC may include only one type of transistor among the silicon transistor S-TFT or the oxide transistor O-TFT.

Referring to FIG. 6, the base layer BL is illustrated as a single layer. The base layer BL may include a synthetic resin, such as polyimide. The base layer BL may be formed by coating a working substrate (or a carrier substrate) with a synthetic resin layer. When the display module DM is completed through a follow-up process, the working substrate may be removed.

Referring to FIG. 6, a barrier layer BRL may be located on (“located on,” as used below, may mean “above”) the base layer BL. The barrier layer BRL reduces or prevents inflow of foreign substances from the outside. The barrier layer BRL may include at least one inorganic layer. The barrier layer BRL may include a silicon oxide layer and a silicon nitride layer. Each of the silicon oxide layer and the silicon nitride layer may be provided in plurality and the silicon oxide layers and the silicon nitride layers may be alternately laminated.

The barrier layer BRL may include a lower barrier layer BRL1 and an upper barrier layer BRL2. A first shielding electrode BML1 may be located between the lower barrier layer BRL1 and the upper barrier layer BRL2. The first shielding electrode BML1 may correspond to the silicon transistor S-TFT. The first shielding electrode BML1 may include a metal, for example, molybdenum.

The first shielding electrode BML1 may receive a bias voltage. The first shielding electrode BML1 may also receive the first power voltage. The first shielding electrode BML1 may reduce or prevent the likelihood of an electrical potential due to a polarization phenomenon affecting the silicon transistor S-TFT. The first shielding electrode BML1 may reduce or prevent the likelihood of an external light beam reaching the silicon transistor S-TFT. In one or more embodiments of the present disclosure, the first shielding electrode BML1 may also be a floating electrode that is isolated from other electrodes or wiring lines.

A buffer layer BFL may be located on the barrier layer BRL. The buffer layer BFL may reduce or prevent metal atoms or impurities being diffused from the base layer BL to an upper first semiconductor pattern SC1. The buffer layer BFL may include at least one inorganic layer. The buffer layer BFL may include a silicon oxide layer and a silicon nitride layer.

The first semiconductor pattern SC1 may be located on the buffer layer BFL. The first semiconductor pattern SC1 may include a silicon semiconductor. For example, the silicon semiconductor may include amorphous silicon, polycrystalline silicon, or the like. For example, the first semiconductor pattern SC1 may include a low-temperature polysilicon.

The first semiconductor pattern SC1 may have different electrical properties depending on whether the first semiconductor pattern SC1 is doped. The first semiconductor pattern SC1 may include a first area having relatively high conductivity and a second area having relatively low conductivity. The first area may be doped with an N-type dopant or a P-type dopant. A P-type transistor may include a doped area doped with the P-type dopant, and an N-type transistor may include a doped area doped with the N-type dopant. The second area may be a non-doped area, or may be an area doped at a concentration that is lower than that of the first area. In one or more embodiments, the first semiconductor pattern SC1 may be the N-type transistor.

A conductivity of the first area may be greater than a conductivity of the second area, and the first area may substantially serve as an electrode or a signal line. The second area may substantially correspond to a channel area (or an active area) of the transistor. In other words, a portion of the first semiconductor pattern SC1 may be a channel of the transistor, another portion of the first semiconductor pattern SC1 may be a source or drain of the transistor, and still another portion of the first semiconductor pattern SC1 may be a connection electrode or connection signal line.

A source area SE1, a channel area AC1 (or an active area), and a drain area DE1 of the silicon transistor S-TFT may be formed from the first semiconductor pattern SC1. The source area SE1 and the drain area DE1 may respectively extend in opposite directions from the channel area AC1 on a cross-section.

A first insulating layer 10 may be located on the buffer layer BFL. The first insulating layer 10 may cover the first semiconductor pattern SC1. The first insulating layer 10 may be an inorganic layer. The first insulating layer 10 may be a single-layer silicon oxide layer. The first insulating layer 10 as well as the inorganic layer of the circuit layer DP-CL, which will be described below, may have a single-layer or multi-layer structure and include at least one of the above-described materials, but the present disclosure is not limited thereto.

A gate GT1 of the silicon transistor S-TFT is located on the first insulating layer 10. The gate GT1 may be a portion of a metal pattern. The gate GT1 overlaps the channel area AC1. In a process of doping the first semiconductor pattern SC1, the gate GT1 may function as a mask. A first electrode CE10 of the capacitor Cst is located on the first insulating layer 10. Unlike the illustration of FIG. 6, the first electrode CE10 may have an integrated shape with the gate GT1.

A second insulating layer 20 may be located on the first insulating layer 10, and may cover the gate GT1. In one or more embodiments of the present disclosure, an upper electrode overlapping the gate GT1 may be further located on the second insulating layer 20. A second electrode CE20 overlapping the first electrode CE10 may be located on the second insulating layer 20. The upper electrode may have an integral shape with, or may be the same as, the second electrode CE20 on a plane.

A second shielding electrode BML2 is located on the second insulating layer 20. The second shielding electrode BML2 may correspond to the oxide transistor O-TFT. In one or more embodiments of the present disclosure, the second shielding electrode BML2 may be omitted. According to one or more embodiments of the present disclosure, the first shielding electrode BML1 may extend to a lower portion of the oxide transistor O-TFT and replace the second shielding electrode BML2.

A third insulating layer 30 may be located on the second insulating layer 20. A second semiconductor pattern SC2 may be located on the third insulating layer 30. The second semiconductor pattern SC2 may include a channel area AC2 of the oxide transistor O-TFT. The second semiconductor pattern SC2 may include a metal oxide semiconductor. The second semiconductor pattern SC2 may include a transparent conductive oxide (TCO), such as indium tin oxide (ITO), indium zinc oxide (IZO), indium gallium zinc oxide (IGZO), zinc oxide (ZnOₓ), or indium oxide (In₂O₃).

The metal oxide semiconductor may include a plurality of areas SE2, AC2, and DE2 divided according to whether the TCO is reduced. An area (hereinafter, referred to as a reduced area), in which the TCO is reduced, may have higher conductivity than that of an area (hereinafter, a non-reduced area), in which the TCO is not reduced. The reduced area substantially serves as a source area/drain area of a transistor or a signal line. The non-reduced area substantially corresponds to a semiconductor area (or a channel area) of the transistor. In other words, a partial area of the second semiconductor pattern SC2 may be the semiconductor area of the transistor, another partial area thereof may be the source area SE2/the drain area DE2 of the transistor, and still another partial area thereof may be a signal transmission area.

A fourth insulating layer 40 may be located on the third insulating layer 30. As illustrated in FIG. 6, the fourth insulating layer 40 may cover the second semiconductor pattern SC2. In one or more embodiments of the present disclosure, the fourth insulating layer 40 may be an insulating pattern that overlaps a gate GT2 of the oxide transistor O-TFT, and that exposes the source area SE2 and the drain area DE2 of the oxide transistor O-TFT.

The gate GT2 of the oxide transistor O-TFT is located on the fourth insulating layer 40. The gate GT2 of the oxide transistor O-TFT may be a portion of the metal pattern. The gate GT2 of the oxide transistor O-TFT overlaps the channel area AC2.

A fifth insulating layer 50 may be located on the fourth insulating layer 40, and the fifth insulating layer 50 may cover the gate GT2. Each of the first insulating layer 10 to the fifth insulating layer 50 may be an inorganic layer.

A first connection pattern CNP1 and a second connection pattern CNP2 may be arranged on the fifth insulating layer 50. The first connection pattern CNP1 and the second connection pattern CNP2 may be formed through the same process and thus may have the same material and the same laminated structure. The first connection pattern CNP1 may be connected to the drain area DE1 of the silicon transistor S-TFT through a first pixel-contact hole PCH1 passing through the first to fifth insulating layers 10, 20, 30, 40, and 50. The second connection pattern CNP2 may be connected to the source area SE2 of the oxide transistor O-TFT through a second pixel-contact hole PCH2 passing through the fourth and fifth insulating layers 40 and 50. The connection relationship between the first connection pattern CNP1 and the second connection pattern CNP2 for the silicon transistor S-TFT and the oxide transistor O-TFT is not necessarily limited thereto.

A sixth insulating layer 60 may be located on the fifth insulating layer 50. A third connection pattern CNP3 may be located on the sixth insulating layer 60. The third connection pattern CNP3 may be connected to the first connection pattern CNP1 through a third pixel-contact hole PCH3 passing through the sixth insulating layer 60. The data line DL may be located on the sixth insulating layer 60. A seventh insulating layer 70 may be located on the sixth insulating layer 60, and may cover the third connection pattern CNP3 and the data line DL. The third connection pattern CNP3 and the data line DL may be formed through the same process, and thus may have the same material and the same laminated structure. Each of the sixth insulating layer 60 and the seventh insulating layer 70 may be an organic layer.

The first shielding electrode BML1, the gate GT1 of the silicon transistor S-TFT, the second electrode CE20, and the gate GT2 of the oxide transistor O-TFT may include molybdenum (Mo), an alloy containing molybdenum, titanium (Ti), or an alloy containing titanium, which has suitable heat resistance. The first connection pattern CNP1 and the second connection pattern CNP2 may include aluminum, which has relatively high electrical conductivity. The first connection pattern CNP1 and the second connection pattern CNP2 may have a three-layer structure in which titanium/aluminum/titanium are laminated.

The light-emitting element LD may include an anode AE (or a first electrode), a light-emitting layer EL, and a cathode CE (or a second electrode). The anode AE of the light-emitting element LD may be located on the seventh insulating layer 70. The anode AE may be a transmissive electrode, a semi-transmissive electrode, or a reflective electrode. The anode AE may include a laminated structure in which ITO/Ag/ITO are sequentially laminated. The positions of the anode AE and the cathode CE may be changed to each other.

A pixel-defining film PDL may be located on the seventh insulating layer 70. The pixel-defining film PDL may be an organic layer. The pixel-defining film PDL may have a property of absorbing a light beam, and for example, the pixel-defining film PDL may have a black color. The pixel-defining film PDL may include a black coloring agent. The black coloring agent may include black dye and black pigment. The black coloring agent may include carbon black, metal, such as chromium, or an oxide thereof. The pixel-defining film PDL may correspond to a light-shielding pattern having light-shielding characteristics.

The pixel-defining film PDL may cover a portion of the anode AE. For example, an opening PDL-OP through which the portion of the anode AE is exposed may be defined in the pixel-defining film PDL. A light-emitting area LA may be defined to correspond to the opening PDL-OP. In one or more embodiments of the present disclosure, a hole control layer may be located between the anode AE and the light-emitting layer EL. The hole control layer may include a hole transport layer and may further include a hole injection layer. An electron control layer may be located between the light-emitting layer EL and the cathode CE. The electron control layer may include an electron transport layer, and may further include an electron injection layer.

The encapsulation layer TFE may cover the light-emitting element LD. The encapsulation layer TFE may include a first encapsulation insulating layer IL1, a second encapsulation insulating layer IL2, and a third encapsulation insulating layer IL3. However, the present disclosure is not limited thereto, and the encapsulation layer TFE may further include a plurality of inorganic layers and a plurality of organic layers.

The first encapsulation insulating layer IL1 may be an inorganic layer. The first encapsulation insulating layer IL1 may reduce or prevent external moisture or oxygen penetrating into the light-emitting element LD. For example, the first encapsulation insulating layer IL1 may include silicon nitride, silicon oxide, or a compound obtained by combining them. The first encapsulation insulating layer IL1 may be formed through a chemical vapor deposition process.

The second encapsulation insulating layer IL2 may be an organic layer. The second encapsulation insulating layer IL2 may be located on the first encapsulation insulating layer IL1, and may be in contact with the first encapsulation insulating layer IL1. The second encapsulation insulating layer IL2 may provide a flat surface onto the first encapsulation insulating layer IL1. Curves formed in an upper surface of the first encapsulation insulating layer IL1, and particles present on the first encapsulation insulating layer IL1, may be covered by the second encapsulation insulating layer IL2, and thus the likelihood of a surface condition of the upper surface of the first encapsulation insulating layer IL1 affecting components formed on the second encapsulation insulating layer IL2 may be reduced or prevented. Further, the second encapsulation insulating layer IL2 may alleviate stresses between contact layers. The second encapsulation insulating layer IL2 may be formed through a solution process, such as spin coating, slit coating, and an inkjet process.

The third encapsulation insulating layer IL3 is located on the second encapsulation insulating layer IL2, and may cover the second encapsulation insulating layer IL2. The third encapsulation insulating layer IL3 may be stably formed on a relatively flat surface as compared to a state in which the third encapsulation insulating layer IL3 is located on the first encapsulation insulating layer IL1. The third encapsulation insulating layer IL3 may reduce or prevent moisture from being introduced from the outside.

The third encapsulation insulating layer IL3 may be optically transparent. For example, the third encapsulation insulating layer IL3 may have a visible light transmittance of about 90% or more. The third encapsulation insulating layer IL3 may have a relatively high light transmittance as compared to the first encapsulation insulating layer IL1. The third encapsulation insulating layer IL3 may be an inorganic layer. The third encapsulation insulating layer IL3 may include silicon oxide (SiOₓ) or silicon oxy nitride (SiON). The third encapsulation insulating layer IL3 may be formed through a chemical vapor deposition process. Meanwhile, each of the first encapsulation insulating layer IL1, the second encapsulation insulating layer IL2, and the third encapsulation insulating layer IL3 may include a plurality of layers, but the present disclosure is not limited to one or more embodiments.

The input-sensing layer ISL may include at least one conductive layer (or at least one sensor-conductive layer), and at least one insulating layer (or at least one sensor insulating layer). In one or more embodiments, the input-sensing layer ISL may include a first detection-insulating layer IS-IL1, a first conductive layer ICL1, a second insulating layer IS-IL2, a second conductive layer ICL2, and a third insulating layer IS-IL3. FIG. 6 briefly illustrates a conductive line of the first conductive layer ICL1 and a conductive line of the second conductive layer ICL2.

The first detection-insulating layer IS-IL1 may be directly located on the display panel DP. The first detection-insulating layer IS-IL1 may be an inorganic layer including at least one of silicon nitride, silicon oxy nitride, and silicon oxide. Each of the first conductive layer ICL1 and the second conductive layer ICL2 may have a single-layer structure or have a multi-layer structure in which layers are laminated in the third direction DR3. The first conductive layer ICL1 and the second conductive layer ICL2 may include conductive lines that define a mesh-shaped electrode. The conductive line of the first conductive layer ICL1 and the conductive line of the second conductive layer ICL2 may or may not be connected through a contact hole passing through the second insulating layer IS-IL2. A connection relationship between the conductive line of the first conductive layer ICL1 and the conductive line of the second conductive layer ICL2 may be determined depending on the type of sensor formed in the input-sensing layer ISL.

The first conductive layer ICL1 and the second conductive layer ICL2 having a single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnOₓ), or indium zinc tin oxide (IZTO). In addition, the transparent conductive layer may include a conductive polymer, such as poly(3,4-ethylenedioxythiophene) (PEDOT), metal nanowires, graphene, or the like.

The first conductive layer ICL1 and the second conductive layer ICL2 having a multi-layer structure may include metal layers. The metal layers may, for example, have a three-layer structure of titanium/aluminum/titanium. The conductive layer having the multi-layer structure may include at least one metal layer and at least one transparent conductive layer. The second insulating layer IS-IL2 may be located between the first conductive layer ICL1 and the second conductive layer ICL2. The third insulating layer IS-IL3 may cover the second conductive layer ICL2. In one or more embodiments of the present disclosure, the third insulating layer IS-IL3 may be omitted. The second insulating layer IS-IL2 and the third insulating layer IS-IL3 may include an inorganic layer or an organic layer.

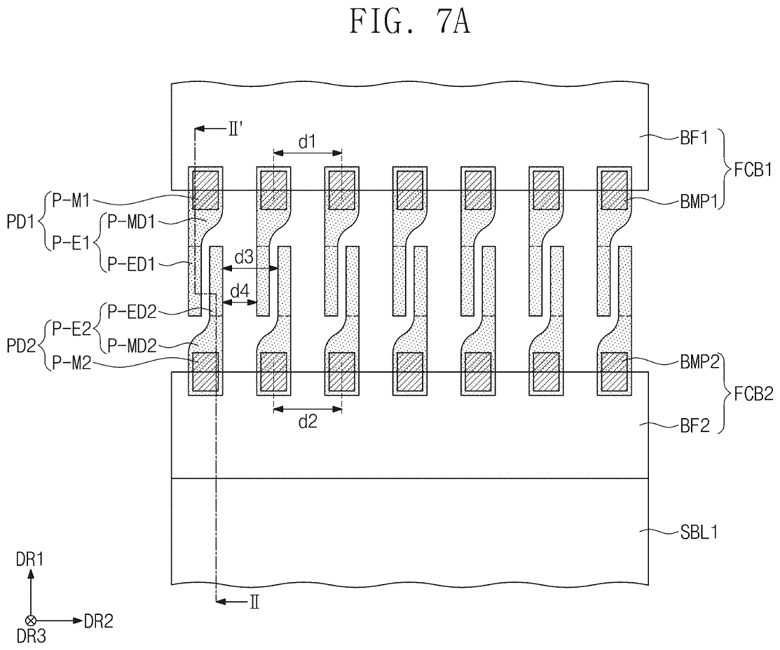

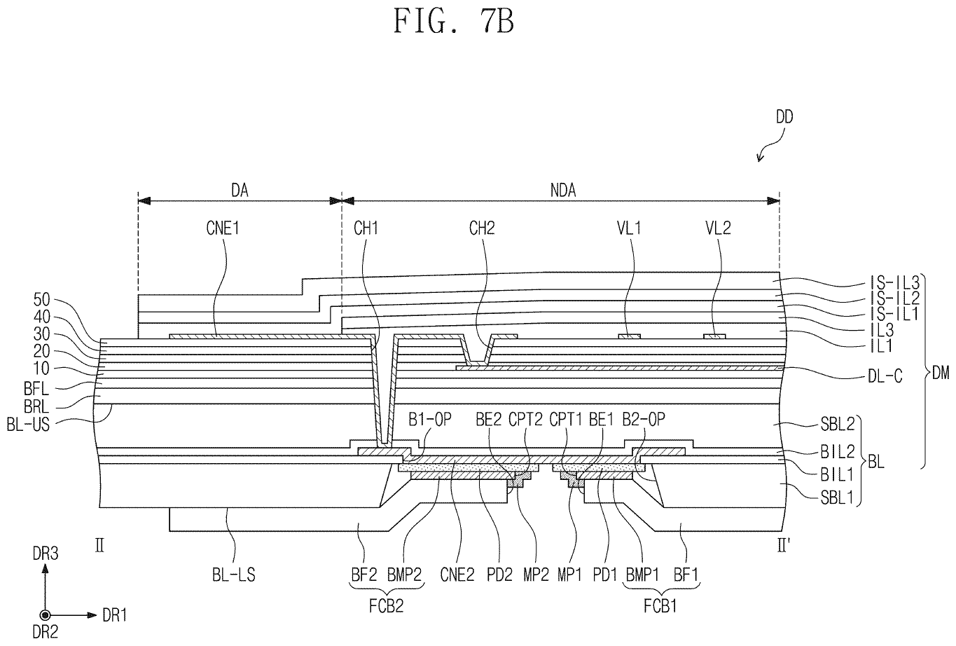

FIG. 7A is an enlarged view of a portion of the display device according to the present disclosure. FIG. 7B is a cross-sectional view of the display module along the line II-II′ of FIG. 7A. Hereinafter, a description duplicated with the above description will be omitted, and a structure, in which the display module DM and the flexible circuit boards FCB1 and FCB2 are connected to each other, will be described with reference to FIGS. 7A and 7B.

Referring to FIGS. 7A and 7B, the display device DD of the present disclosure may include a first connection electrode CNE1 (or a connection pattern) and a second connection electrode CNE2 (or a connection electrode). The first connection electrode CNE1 may be at the same layer as that of the first connection pattern CNP1 illustrated in FIG. 6, and a portion of a data connection line DL-C overlapping the non-display area DM-NDA may be at the same layer as that of the gate GT1 of the silicon transistor S-TFT in FIG. 6. The data connection line DL-C may be electrically connected to the data line DL.

The second connection electrode CNE2 may be exposed to the outside through a lower surface BL-LS of the base layer BL for rear surface bonding with the flexible circuit boards FCB1 and FCB2. However, the present disclosure is not limited thereto, and the second connection electrode CNE2 may not be directly exposed to the outside, but instead may be exposed to the outside through a contact hole or the like. The lower surface BL-LS of the base layer BL faces an upper surface BL-US of the base layer BL in the third direction DR3.

The base layer BL may include a first sub-base layer SBL1, a first base-insulating layer BIL1, a second base-insulating layer BIL2, and a second sub-base layer SBL2. The first base-insulating layer BIL1 is located on the first sub-base layer SBL1, and the second base-insulating layer BIL2 is located on the first base-insulating layer BIL1 and covers the second connection electrode CNE2 (e.g., the upper surface of the second connection electrode CNE2). The second sub-base layer SBL2 is located on the second base-insulating layer BIL2.

The first sub-base layer SBL1 and the second sub-base layer SBL2 may include a synthetic resin material, for example, polyimide. The first base-insulating layer BIL1 and the second base-insulating layer BIL2 may include an inorganic material. For example, the first base-insulating layer BIL1 and the second base-insulating layer BIL2 may include silicon nitride, silicon oxy nitride, or silicon oxide.

The first base-insulating layer BIL1 is located on the first sub-base layer SBL1, and a first opening B1-OP, through which a portion of the second connection electrode CNE2 is exposed, is defined in the first base-insulating layer BIL1. The first sub-base layer SBL1 may be located under the first base-insulating layer BIL1. The first sub-base layer SBL1 provides the lower surface BL-LS of the base layer BL, and a second opening B2-OP, through which the second connection electrode CNE2 is exposed to the outside of the display module DM, is defined in the first sub-base layer SBL1. The second opening B2-OP may expose a portion of the first base-insulating layer BIL1 (e.g., a lower portion of the first base-insulating layer BIL1) to the outside. A size of the second opening B2-OP may be larger than a size of the first opening B1-OP.

The second connection electrode CNE2 may be embedded in the base layer BL. However, the present disclosure is not limited thereto, and the second connection electrode CNE2 may be located on the lower surface BL-LS of the base layer BL. Even when the base layer BL includes a single-layer synthetic resin layer or a plurality of layers, the first opening B1-OP and the second opening B2-OP, which will be described below, may not be defined. The second connection electrode CNE2 located on the lower surface BL-LS of the base layer BL may be connected to a conductive pattern located on the upper surface BL-US of the base layer BL through a contact hole passing through the base layer BL.

The first connection electrode CNE1 may be connected to the second connection electrode CNE2 through a first contact hole CH1, and may be connected to the data line DL through a second contact hole CH2. The first contact hole CH1 and the second contact hole CH2 may be arranged in the non-display area DM-NDA. The first contact hole CH1 may be formed by passing through portions of the plurality of insulating layers 10, 20, 30, 40, and 50, the barrier layer BRL, the buffer layer BFL, and the base layer BL. The first contact hole CH1 may be connected to the second connection electrode CNE2 through the second base-insulating layer BIL2 and the second sub-base layer SBL2. The second contact hole CH2 may be formed by passing through the second insulating layer 20 to the fifth insulating layer 50. The first connection electrode CNE1 may be connected to the data line DL through the second contact hole CH2.

Referring to FIGS. 7A and 7B, the base layer BL may further include pad electrodes PD1 and PD2 connected to the second connection electrode CNE2. The pad electrodes PD1 and PD2 in contact with the second connection electrode CNE2 may be exposed to the outside through the first opening B1-OP defined in the first sub-base layer SBL1. The pad electrodes PD1 and PD2 may include the first pad electrodes PD1 extending in the first direction DR1, and the second pad electrodes PD2 extending in an opposite direction to the first direction DR1.

The first pad electrodes PD1 and the second pad electrodes PD2 may overlap the non-display area NDA. For example, the first pad electrodes PD1 and the second pad electrodes PD2 may be arranged in the pad area PA illustrated in FIG. 2. The first pad electrodes PD1 and the second pad electrodes PD2 may be arranged in the second direction DR2. The first pad electrodes PD1 and the second pad electrodes PD2 may face each other in the first direction DR1. For example, the first pad electrodes PD1 and the second pad electrodes PD2 (e.g., ends thereof) may be spaced apart from each other in the first direction DR1.

The first flexible circuit board FCB1 may include a first base film BF1, and a first bump electrode BMP1 including a first contact part CPT1 located on (e.g., above) the first base film BF1, and exposed from (e.g., extending beyond) a first edge BE1 of the first base film BF1. The first bump electrode BMP1 may overlap the first pad electrodes PD1 on a plane. The first bump electrode BMP1 may be in contact with, and electrically connected to, the first pad electrodes PD1. A plurality of first bump electrodes BMP1 may be provided. The plurality of first bump electrodes BMP1 may respectively correspond to the plurality of first pad electrodes PD1. That is, one first bump electrode BMP1 may correspond to one first pad electrode PD1. The plurality of first bump electrodes BMP1 may extend in the first direction DR1, and may be arranged in the second direction DR2.

The second flexible circuit board FCB2 may include a second base film BF2, and a second bump electrode BMP2 including a second contact part CPT2 located on the second base film BF2 and exposed from (e.g., extending beyond) a second edge BE2 of the second base film BF2. The second bump electrode BMP2 may overlap the second pad electrodes PD2 on a plane. The second bump electrode BMP2 may be in contact with, and electrically connected to, the second pad electrodes PD2. A plurality of second bump electrodes BMP2 may be provided. The plurality of second bump electrodes BMP2 may respectively correspond to the plurality of second pad electrodes PD2. That is, one second bump electrode BMP2 may correspond to one second pad electrode PD2. The plurality of second bump electrodes BMP2 may extend in the first direction DR1, and may be arranged in the second direction DR2. The plurality of first bump electrodes BMP1 may face the plurality of second bump electrodes BMP2, and may be spaced apart from each other in the first direction DR1.

The first bump electrodes BMP1 may be respectively electrically connected to the first pad electrodes PD1. In detail, the display device DD may further include a first metal pattern MP1 that electrically connects the first bump electrodes BMP1 and the first pad electrodes PD1, and a second metal pattern MP2 that electrically connects the second bump electrodes BMP2 and the second pad electrodes PD2. The first metal pattern MP1 contacts the first pad electrodes PD1 and the first contact part CPT1, and electrically connects the first bump electrodes BMP1 and the first pad electrodes PD1. The second metal pattern MP2 contacts the second pad electrode PD2 and the second contact part CPT2, and electrically connects the second bump electrodes BMP2 and the second pad electrodes PD2.

Each of the first metal pattern MP1 and the second metal pattern MP2 may be a pattern(s) obtained by curing a metal ink. The metal pattern MP may include solder paste. Each of the first metal pattern MP1 and the second metal pattern MP2 may be formed from a metal ink containing silver or copper. The first metal pattern MP1 may be located on each of the first pad electrodes PD1. The second metal pattern MP2 may be located on each of the second pad electrodes PD2.

In one or more embodiments, one or more adhesive layers may be further respectively arranged between the first pad electrodes PD1 and the first bump electrodes BMP1, and between the second pad electrodes PD2 and the second bump electrodes BMP2. When the adhesive layer includes an insulating material, the first pad electrodes PD1 and the first bump electrodes BMP1 may be electrically connected only through the first metal pattern MP1, and the second pad electrodes PD2 and the second bump electrodes BMP2 may be connected only through the second metal pattern MP2.

Each of the first metal pattern MP1 and the second metal pattern MP2 may be formed by curing a metal ink, and then by patterning the metal ink. Each of the first metal pattern MP1 and the second metal pattern MP2 may be formed at relatively low temperature, and the first pad electrodes PD1 and the first bump electrodes BMP1, and the second pad electrodes PD2 and the second bump electrodes BMP2, may be respectively electrically connected to each other, and at the same time, bonded to each other without a pressing process at a high temperature.

The first pad electrodes PD1 may include first main parts P-M1 overlapping the first bump electrodes BMP1 on a plane, and also may include first extension parts P-E1 extending from the first main parts P-M1 in an opposite direction to the first direction DR1. The second pad electrodes PD2 may include second main parts P-M2 overlapping the second bump electrodes BMP2 on a plane, and also may include second extension parts P-E2 extending from the second main parts P-M2 in the first direction DR1.

The first main parts P-M1 and the second main parts P-M2 may be arranged in the second direction DR2, and may be spaced apart from each other to face each other in the first direction DR1. The first main parts P-M1 and the second main parts P-M2 may overlap each other in the first direction DR1. However, one or more embodiments is not limited thereto, and, for example, only some of the first main parts P-M1 and the second main parts P-M2 may overlap each other in the first direction DR1. According to one or more embodiments of the present disclosure, pitches d1 between adjacent ones of the first main parts P-M1 may be greater than or equal to about 30 μm and less than or equal to about 50 μm. For example, the pitches d1 between the first main parts P-M1 adjacent to each other may be about 40 μm. All the pitches d1 between the first main parts P-M1 adjacent to each other may be the same. However, the present disclosure is not limited thereto, and the pitches d1 between the first main parts P-M1 adjacent to each other may be different from each other. Pitches d2 between the second main parts P-M2 adjacent to each other may be equal to the pitches d1 between the first main parts P-M1 adjacent to each other.

Referring to FIGS. 7A and 7B, the first extension parts P-E1 are parts exposed from the first bump electrodes BMP1. That is, the first extension parts P-E1 may be parts exposed from the first bump electrodes BMP1, and electrically connected to the first contact part CPT1 through the first metal pattern MP1. The first extension parts P-E1 may be aligned in the second direction DR2. The second extension parts P-E2 are parts exposed from the second bump electrodes BMP2. That is, the second extension parts P-E2 may be parts exposed from the second bump electrodes BMP2 and electrically connected to the second contact part CPT2 through the second metal pattern MP2. The second extension parts P-E2 may be aligned in the second direction DR2.

Referring back to FIG. 7B, the first extension parts P-E1 and the second extension parts P-E2 may be spaced apart from each other in the first direction DR1. The first extension parts P-E1 and the second extension parts P-E2 may not overlap each other on a plane. According to one or more embodiments of the present disclosure, the first extension parts P-E1 and the second extension parts P-E2 may include parts whose widths with respect to the second direction DR2 (e.g., gradually decrease). For example, the first extension parts P-E1 include parts whose widths decrease (e.g., gradually decrease) in an opposite direction to the first direction DR1, and the second extension parts P-E2 may include parts whose widths (e.g., gradually decrease) in the first direction DR1. The first extension parts P-E1 may include first middle parts P-MD1, whose widths gradually decrease, and first ends P-ED1 extending from the first middle parts P-MD1. The second extension parts P-E2 may include second middle parts P-MD2, whose widths gradually decrease, and second ends P-ED2 extending from the second middle parts P-MD2.

According to one or more embodiments of the present disclosure, the first extension parts P-E1 and the second extension parts P-E2 may be alternately arranged in the second direction DR2. The first extension parts P-E1 and the second extension parts P-E2 may include parts that overlap each other in the second direction DR2. As described above, parts of the first extension parts P-E1, whose width decreases and the second extension parts P-E2, whose width decreases, may face each other. In detail, the first ends P-ED1 and the second ends P-ED2 may face each other, and may be arranged alternately. It is illustrated in FIG. 7A that the first extension parts P-E1 and the second extension parts P-E2 are arranged alternately in the second direction DR2, but the present disclosure is not limited thereto, and the first extension parts P-E1 and the second extension parts P-E2 may be arranged alternately in groups of two.

A gap between adjacent ones of the second ends P-ED2 in the second direction DR2 may be defined as a third gap d3, and a gap (e.g., one of the gaps) between adjacent ones of the second ends P-ED2 and the first ends P-ED1 in the second direction DR2 may be defined as a fourth gap d4. The third gap d3 may be greater than the fourth gap d4.

The display device DD of the present disclosure may include the first flexible circuit board FCB1 and the second flexible circuit board FCB2 spaced apart from each other in the first direction DR1. According to one or more embodiments of the present disclosure, the first pad electrodes PD1 may be in contact with the first bump electrodes BMP1 of the first flexible circuit board FCB1 to be electrically connected to each other. The second pad electrodes PD2 may be in contact with the second bump electrodes BMP2 of the second flexible circuit board FCB2 to be electrically connected to each other.

When pitches between the first pad electrodes PD1 aligned in the second direction DR2 are less than or equal to a corresponding gap, defects may occur due to misalignment between the first bump electrodes BMP1 and the first pad electrodes PD1. Likewise, when pitches between the second pad electrodes PD2 aligned in the second direction DR2 are less than or equal to a corresponding gap, defects may occur due to misalignment between the second bump electrodes BMP2 and the second pad electrodes PD2.

As the first flexible circuit board FCB1 and the second flexible circuit board FCB2 spaced apart from each other in the first direction DR1 are arranged under the display module DM, the pitches d1 between the first main parts P-M1 of the first pad electrodes PD1 adjacent to each other, and the pitches d2 between the second main parts P-M2 of the second pad electrodes PD2 adjacent to each other, may be greater than or equal to about 30 μm and less than and equal to about 50 μm. As a result, when the first flexible circuit board FCB1 and the display module DM are in contact with each other, defects due to alignment between the first bump electrodes BMP1 and the first pad electrodes PD1 may be reduced or prevented, and when the second flexible circuit board FCB2 and the display module DM are in contact with each other, defects due to alignment between the second bump electrodes BMP2 and the second pad electrodes PD2 may be reduced or prevented.

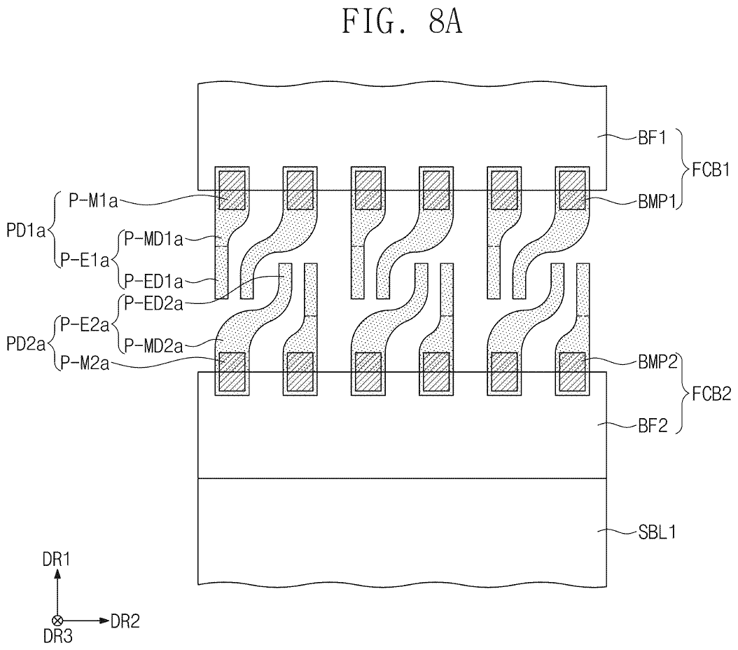

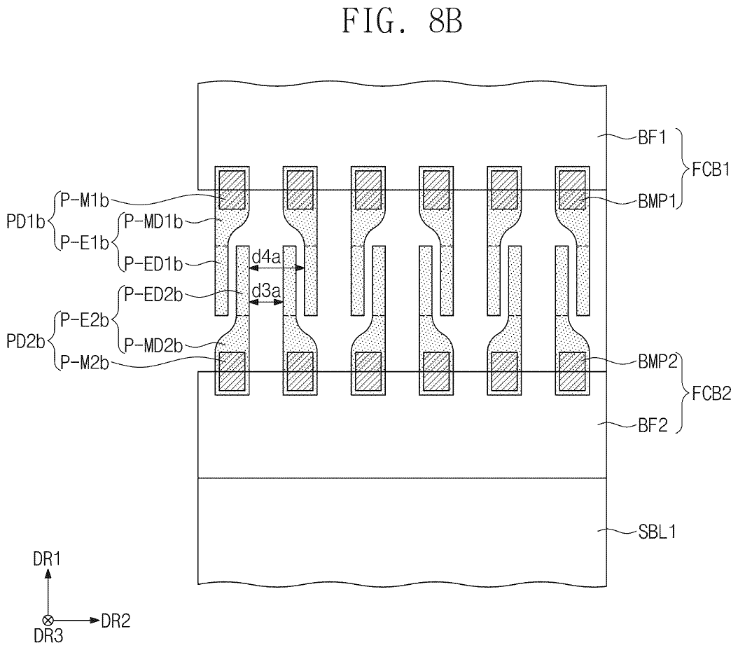

FIGS. 8A and 8B are enlarged views of a portion of the display device of the present disclosure.

Referring to FIG. 8A, first pad electrodes PD1a may include first main parts P-M1a overlapping the first bump electrodes BMP1 on a plane, and first extension parts P-E1a extending from the first main parts P-M1a in an opposite direction to the first direction DR1. Second pad electrodes PD2a may include second main parts P-M2a overlapping the second bump electrodes BMP2 on a plane, and second extension parts P-E2a extending from the second main parts P-M2a in the first direction DR1.

The first main parts P-M1a and the second main parts P-M2a may be arranged along the second direction DR2, and may be spaced apart from each other to face each other in the first direction DR1. The first main parts P-M1a and the second main parts P-M2a may overlap each other in the first direction DR1.

According to one or more embodiments of the present disclosure, the first extension parts P-E1a and the second extension parts P-E2a may include parts whose widths in the second direction DR2 decrease (e.g., gradually decrease). The first extension parts P-E1a may include first middle parts P-MD1a whose widths decrease (e.g., gradually decrease) and first ends P-ED1a extending from the first middle parts P-MD1a, and the second extension parts P-E2a may include second middle parts P-MD2a whose widths decrease (e.g., gradually decrease) and second ends P-ED2a extending from the second middle parts P-MD2a.

The first ends P-ED1a and the second ends P-ED2a may face each other, and may be arranged alternately. In detail, two first ends P-ED1a adjacent to each other and two second ends P-ED2a adjacent to each other (e.g., without any first ends P-ED1a intervening) may be alternately arranged in the second direction DR2. For example, one or more of the first ends P-ED1a and/or one or more of the second ends P-ED2a may extend along both the first direction DR1 and the second direction DR2 from the respective first middle parts P-MD1a and second middle parts P-MD2a. The present disclosure is not limited thereto, and the first ends P-ED1a and the second ends P-ED2a may be alternately arranged in groups of three.

Referring to FIG. 8B, first pad electrodes PD1b may include first main parts P-M1b overlapping the first bump electrodes BMP1 on a plane, and first extension parts P-E1b extending from the first main parts P-M1b in an opposite direction to the first direction DR1. Second pad electrodes PD2b may include second main parts P-M2b overlapping the second bump electrodes BMP2 on a plane, and second extension parts P-E2b extending from the second main parts P-M2b in the first direction DR1.

The first extension parts P-E1b may include first middle parts P-MD1b whose widths decrease (e.g., gradually decrease), and first ends P-ED1b extending from the first middle parts P-MD1b. The second extension parts P-E2b may include second middle parts P-MD2b whose widths decrease (e.g., gradually decrease), and second ends P-ED2b extending from the second middle parts P-MD2b.

As shown in FIG. 8B, directions in which widths of the first middle parts P-MD1b adjacent to each other and of the second middle parts P-MD2b adjacent to each other decrease may be different from each other. The directions in which the widths of the first middle parts P-MD1 and the second middle parts P-MD2 illustrated in FIG. 7A decrease may be the same. However, the directions in which the widths of the first middle parts P-MD1b and the second middle parts P-MD2b decrease (e.g., the directions in which respective edges adjust along the first direction DR1 to effectuate the decreasing widths with respect to the second direction DR2) may alternate with each other, and thus the widths may decrease with an edge moving in the second direction DR2 or may then decrease with another edge moving in an opposite direction to the second direction DR2.

A gap between adjacent ones of the second ends P-ED2b in the second direction DR2 may be defined as a third gap d3a, and a gap (e.g., one of the gaps) between adjacent ones of the second ends P-ED2b and the first ends P-ED1b in the second direction DR2 may be defined as a fourth gap d4a. The fourth gap d4a may be greater than the third gap d3a.

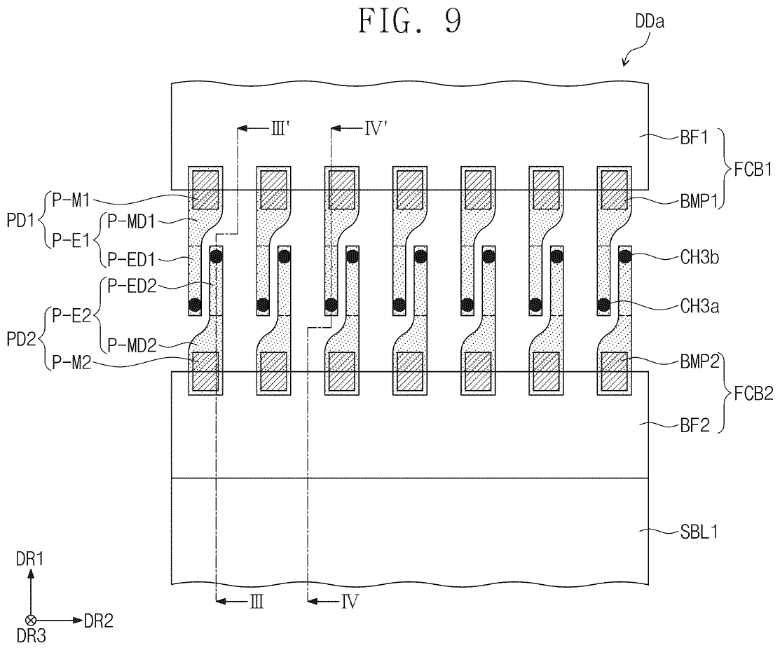

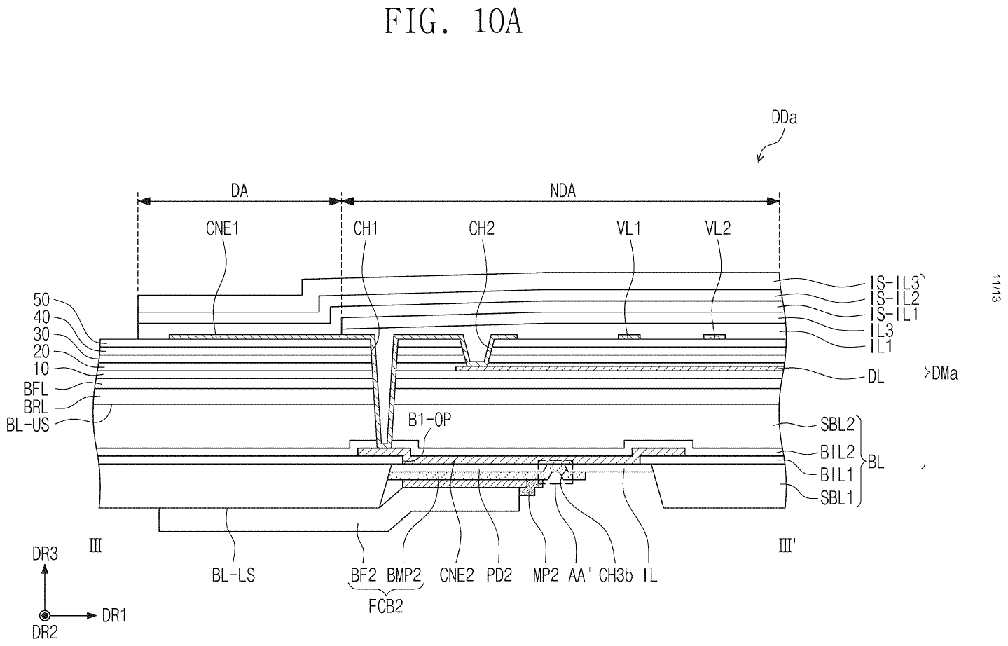

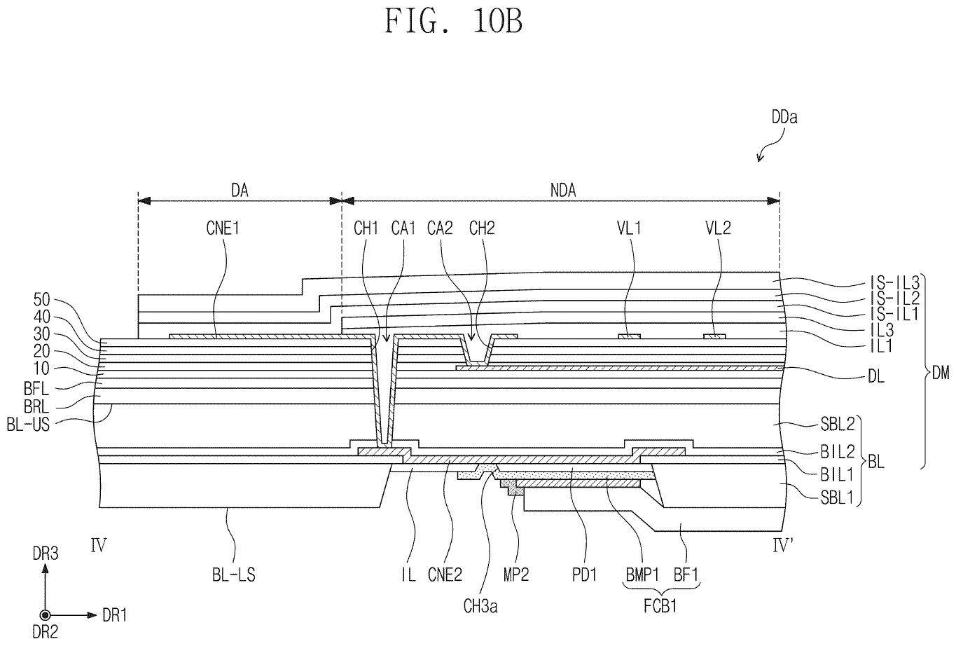

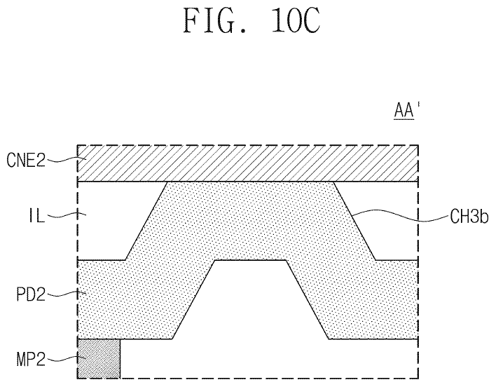

FIG. 9 is an enlarged view of a portion of a display device DDa of the present disclosure. FIG. 10A is a cross-sectional view of a display module DMa along the line III-III′ of FIG. 9. FIG. 10B is a cross-sectional view of the display module DMa along the line IV-IV′ of FIG. 9. FIG. 10C is an enlarged view of area AA′ of FIG. 10A.

Referring to FIGS. 9 to 10C, an insulating layer IL may be arranged between the pad electrodes PD1 and PD2 and the second connection electrode CNE2, and third contact holes CH3a and CH3b (or contact holes) may be formed in the insulating layer IL. The insulating layer IL may cover a lower surface of the second connection electrode CNE2. The insulating layer IL may include an inorganic material, and for example, the insulating layer IL may include silicon nitride, silicon oxy nitride, or silicon oxide. However, the present disclosure is not limited thereto, and the insulating layer IL may include the same material as the first sub-base layer SBL1. For example, the insulating layer IL may include a synthetic resin material, for example, polyimide. The insulating layer IL may be formed integrally with the first sub-base layer SBL1.

Referring to FIGS. 9, 10A, and 10C, the third contact hole CH3b may be formed in the insulating layer IL. The second pad electrodes PD2 and the second connection electrode CNE2 may be electrically connected through the third contact hole CH3b formed in the insulating layer IL. As illustrated in FIG. 9, a plurality of third contact holes CH3b may be provided. That is, the third contact holes CH3b may be formed in the second pad electrodes PD2, respectively. In detail, the third contact holes CH3b may be formed at the second ends P-ED2 of the second pad electrodes PD2. It is illustrated that one third contact hole CH3b is formed in a corresponding one of the second pad electrodes PD2, but the present disclosure is not limited thereto, and the two or more third contact holes CH3b may be formed in one second pad electrode PD2. The third contact holes CH3b may be arranged in the second direction DR2. As illustrated, the third contact holes CH3b may be arranged side by side in the second direction DR2, but the present disclosure is not limited thereto, and the third contact holes CH3b may be formed at arbitrary portions of the second ends P-ED2, and thus need not be arranged side by side in the second direction DR2. The third contact holes CH3a and CH3b may be arranged in a zigzag pattern on a plane.

Referring to FIGS. 9 and 10B, the third contact hole CH3a may be formed in the insulating layer IL. The first pad electrodes PD1 and the second connection electrode CNE2 may be electrically connected through the third contact hole CH3a formed in the insulating layer IL. As illustrated in FIG. 9, a plurality of third contact holes CH3a may be provided. That is, the third contact holes CH3a may be formed in the first pad electrodes PD1, respectively. In detail, the third contact holes CH3a may be formed at the first ends P-ED1 of the first pad electrodes PD1. It is illustrated that one third contact hole CH3a is formed in a corresponding one of the first pad electrodes PD1, but the present disclosure is not limited thereto, and the two or more third contact holes CH3a may be formed in one first pad electrode PD1. The third contact holes CH3a may be arranged in the second direction DR2. As illustrated, the third contact holes CH3a may be arranged side by side in the second direction DR2, but the present disclosure is not limited thereto, and the third contact holes CH3a may be formed at arbitrary portions of the first ends P-ED1, and thus need not be arranged side by side in the second direction DR2.

According to the present disclosure, a flexible circuit board is bonded to a rear surface of a display panel (rear surface bonding). Because a non-display area of the display panel is not bent, defects that may occur when the non-display area of the display panel is bent may be reduced or prevented. An area of a bezel area of a window for covering the non-display area of the display panel may be reduced.

A metal pattern formed by curing and then patterning a metal ink electrically connects the flexible circuit board and a pad electrode. The metal pattern may be formed at a low temperature, and may bond the flexible circuit board and the display panel without a process of pressing the flexible circuit board and the display panel at a high temperature.

As a first flexible circuit board and a second flexible circuit board of a display module, which are spaced apart from each other, are arranged, a pitch between first pad electrodes adjacent to each other and a pitch between second pad electrodes adjacent to each other may be a corresponding gap or more. As a result, defects due to alignment between first bump electrodes and the first pad electrodes of the first flexible circuit board and second bump electrodes and the second pad electrodes of the second flexible circuit board may be reduced or prevented.

Although the description has been made above with reference to one or more embodiments of the present disclosure, it may be understood that those skilled in the art or those having ordinary knowledge in the art may variously modify and changes the present disclosure without departing from the spirit and technical scope of the present disclosure described in the appended claims. Thus, the technical scope of the present disclosure is not limited to the detailed description of the specification, but should be defined by the appended claims, with functional equivalents thereof to be included therein.

What is claimed is:

1. A display device comprising:
a first circuit board;
a second circuit board; and
a display panel electrically connected to the first circuit board and the second circuit board, defining a display area and a non-display area; and comprising:
a base layer comprising:
a first sub-base layer overlapping the display area and the non-display area;
a second sub-base layer above the first sub-base layer;
a connection electrode between the first sub-base layer and the second sub-base layer, and electrically connected to a signal line; and
pad electrodes exposed through an opening defined in the first sub-base layer, electrically connected to the connection electrode, and comprising:
first pad electrodes electrically connected to the first circuit board, and extending in a first direction; and
second pad electrodes electrically connected to the second circuit board, spaced apart from the first pad electrodes in the first direction, and extending in an opposite direction to the first direction; and
a circuit layer above the base layer, and comprising a transistor, and at least one signal line connected to the transistor.

2. The display device of claim 1, wherein the first circuit board comprises a first base film, and a first bump electrode above the first base film, and
wherein the second circuit board comprises a second base film, and a second bump electrode above the second base film.

3. The display device of claim 1, wherein the first circuit board comprises a first base film, and first bump electrodes above the first base film, and
wherein the second circuit board comprises a second base film, and second bump electrodes above the second base film and facing the first bump electrodes in the first direction.

4. The display device of claim 3, wherein the first pad electrodes respectively contact the first bump electrodes, and
wherein the second pad electrodes respectively contact the second bump electrodes.

5. The display device of claim 2, wherein the first bump electrode comprises a first contact part extending beyond an edge of the first base film, and
wherein the second bump electrode comprises a second contact part extending beyond an edge of the second base film.

6. The display device of claim 5, further comprising:
a first metal pattern electrically connecting the first bump electrode and the first pad electrodes; and
a second metal pattern electrically connecting the second bump electrode and the second pad electrodes,
wherein the first metal pattern contacts the first pad electrodes and the first contact part, and
wherein the second metal pattern contacts the second pad electrodes and the second contact part.

7. The display device of claim 6, further comprising:
a first adhesive layer between the first bump electrode and the first pad electrodes; and
a second adhesive layer between the second bump electrode and the second pad electrodes.

8. The display device of claim 2, wherein the first pad electrodes comprise:
first main parts overlapping the first bump electrode on a plane; and
first extension parts not overlapping the first bump electrode on a plane, and extending from the first main parts, and
wherein the second pad electrodes comprise:
second main parts overlapping the second bump electrode on a plane; and
second extension parts not overlapping the second bump electrode on a plane, and extending from the second main parts.

9. The display device of claim 8, wherein the first main parts and the second main parts face each other in the first direction, and are arranged in a second direction substantially perpendicular to the first direction.

10. The display device of claim 9, wherein the first extension parts and the second extension parts are alternately arranged in the second direction.

11. The display device of claim 9, wherein the first extension parts and the second extension parts partially overlap each other in the second direction.

12. The display device of claim 8, wherein respective widths of the first extension parts and the second extension parts decrease along the first direction.

13. The display device of claim 1, wherein the first circuit board comprises a bending part bent toward a lower side of the display panel, and
wherein a portion of the first circuit board overlaps the second circuit board on a plane.

14. The display device of claim 1, wherein the first pad electrodes and the second pad electrodes overlap the non-display area.

15. The display device of claim 1, further comprising an insulating layer between the pad electrodes and the connection electrode, the pad electrodes and the connection electrode being electrically connected through a contact hole defined by the insulating layer.

16. The display device of claim 1, further comprising a connection pattern penetrating a portion of the base layer,
wherein the signal line is above an upper surface of the second sub-base layer, and is electrically connected to a corresponding one of the pad electrodes through the connection pattern.

17. A display device comprising:
a display panel defining a display area and a non-display area; and
a first circuit board electrically connected to the display panel, and a second circuit board electrically connected to the display pane and spaced apart from the first circuit board in a first direction,
wherein the display panel comprises:
a base layer comprising:
a first sub-base layer overlapping the display area and the non-display area;
a second sub-base layer above the first sub-base layer;
a connection electrode between the first sub-base layer and the second sub-base layer, and electrically connected to a signal line; and
pad electrodes exposed through an opening defined in the first sub-base layer, electrically connected to the connection electrode, and comprising:
first pad electrodes overlapping the first circuit board and not overlapping the second circuit board; and
second pad electrodes overlapping the second circuit board and not overlapping the first circuit board, at least one of the second pad electrodes facing at least one of the first pad electrodes in a second direction that is substantially perpendicular to the first direction; and
a circuit layer above the base layer, and comprising a transistor and at least one signal line connected to the transistor.

18. The display device of claim 17, wherein the first pad electrodes and the second pad electrodes are spaced apart from each other in the first direction.

19. The display device of claim 18, wherein the first pad electrodes comprise:
first main parts overlapping the first circuit board on a plane; and
first extension parts not overlapping the first circuit board on a plane, and extending from the first main parts, and
wherein the second pad electrodes comprise:
second main parts overlapping the second circuit board on a plane; and
second extension parts not overlapping the second circuit board on a plane, and extending from the second main parts.

20. The display device of claim 19, wherein the first extension parts and the second extension parts are alternately arranged in the second direction.
